(19) United States
(12) Patent Application Publication
(10) Pub. No.: US 2004/0082175 A1
(43) Pub. Date: Apr. 29, 2004

(54) Process for high-dielectric constant metal-insulator metal capacitor in VLSI multi-level metallization systems

(76) Inventor: Osamu Samuel Nakagawa, Redwood City, CA (US)

Correspondence Address: HEWLETT-PACKARD COMPANY, Intellectual Property Administration, P. O. Box 272400, Fort Collins, CO, 80527-2400, US

(21) Appl. No.: 10/690,730

(22) Filed: Oct. 22, 2003

Related U.S. Application Data
(62) Division of application No. 09/891,324, filed on Jun. 27, 2001.

(51) Int. Cl. H01L 21/302; H01L 21/461

(52) U.S. Cl. 438/689

(57) ABSTRACT

A method or process of manufacturing on-chip bypass capacitors on a VLSI device (or chip) is improved by utilizing a high-dielectric constant metal-insulator-metal (MIM) capacitor manufacturing process. The high-k constant MIM capacitor may include a lower electrode in a first metal layer of a VLSI device, a substantially thin layer of high-k insulator (e.g., silicon nitride at an interface of the first metal layer and a via, and an upper electrode form in a second metal layer. The via provides a channel between the second metal layer to the high-k insulator.

### RELATED APPLICATION

The following applications of common assignee, filed concurrently, may contain some common disclosure and may relate to the present invention:

U.S. patent application Serial No. 09/______, entitled “HIGH-DIELECTRIC CONSTANT METAL-INSULATOR METAL CAPACITOR IN VLSI MULTI-LEVEL METALLIZATION SYSTEM” (Attorney Docket No. 10005208-1).

### FIELD OF THE INVENTION

This invention relates generally to VLSI device manufacturing, and more particularly to manufacturing high dielectric constant capacitors in a multi-level metal VLSI devices.

### DESCRIPTION OF THE RELATED ART

In today's high performance very large scale integration (“VLSI”) devices (or chips), the use of on-chip bypass capacitors is essential. For example, in the design of high-performance microprocessors, on-chip bypass capacitors often act as a reservoir of electrical charge, reduce power requirements for the microprocessors, and/or lower the occurrence of ground bounce.

Ground bounce is noise generated by the simultaneous switching of transistor devices of the device. The noise is typically generated during the logic HIGH to LOW transition where the resultant potential difference, i.e., ground bounce, is between the device ground and an external ground. When several outputs of component devices of a VLSI device switch simultaneously, the total build up of current in the common ground or a power lead may be substantial. There may be a complementary effect in a power lead of the device called power bounce. Failure to control power and/or ground bounce may lead to timing failures, spurious switching, and excessive electromagnetic interference. Accordingly, ground and/or power bounce may limit the overall performance of a VLSI device.

On-chip bypass capacitors are commonly implemented by metal oxide semiconductor field effect transistor (“MOSFET”). In order to configure a MOSFET as a capacitor in a VLSI device, the source and gate of the MOSFET are typically connected to a power rail with the gate of the MOSFET connected to a ground of the VLSI device. However, in advanced technology VLSI devices, the transistors are of a scale that the gate thickness of a typical MOSFET capacitor is reduced to the atomic level, e.g., 20 Angstroms (Å). As a result, the gates of MOSFET capacitors are susceptible to a high level of leakage current. The leakage current may lead to undesirable effects in a VLSI device such as higher power consumption, functionality failure during testing, etc. Moreover, another drawback is a MOSFET type on-chip bypass capacitors are spatially large, i.e., consumes valuable silicon area of a VLSI device, thereby increasing the cost of production of the VLSI device.

An alternative to MOSFET capacitors is a metal-insulator-metal (“MIM”) capacitor. A MIM capacitor is typically formed by wiring metals together in a conventional multi-level metallization VLSI system. As it is generally known, a VLSI device may use multiple layers of metal to form interconnections between the component devices of the VLSI device. The MIM capacitors may be formed in a vertical or a horizontal dimensional.

A typical MIM capacitor may have several advantages over a MOSFET capacitor. For instance, leakage current in the MIM capacitors is negligible because of a relatively thick insulating area (200 nm-1 um) between the metals forming a MIM capacitor. Furthermore, MIM capacitors may be built on top of component devices, e.g., transistors, of the VLSI system. As a result, MIM capacitors do not incur an area penalty as suffered by the MOSFET capacitors.

However, MIM capacitors may still have several disadvantages. For example, a MIM capacitor may have a low capacitance per unit area. The typical minimum thickness of an insulator in a MIM capacitor is approximately 2000 Å. The thickness of the MIM capacitor may not be reduced due to current resolution of conventional lithography techniques. Since the typical thickness of a MIM capacitor is 100 times larger than the transistor gate thickness of a MOSFET capacitor, the capacitance of the MIM capacitor is approximately 100 times less than that of a MOSFET capacitor. As it is generally known, capacitance is inversely proportional to insulator thickness. Accordingly, MIM capacitors usually cannot supply sufficient charge to the power rails to suppress power and/or ground bounce.

### SUMMARY OF THE INVENTION

In accordance with the principles of the present invention, a method of forming a by-pass capacitor on a multi-level metallization device is utilized to improve the capacitance per unit area of the by-pass capacitor. The method includes forming a first electrode in a first metal layer of the multi-level metallization device and depositing a substantially thin dielectric material layer over the first metal layer of the multi-level metallization device. The method also includes forming a second electrode on a second metal layer, where the second metal layer is formed over the substantially thin dielectric material layer.

In accordance with another aspect of the principles of the present invention, an on-chip by-pass capacitor is utilized to provide an improved capacitance per unit area capacitor. The on-chip by-pass capacitor includes a first electrode formed during a deposition of a first metal layer of a multi-level deposition device and a substantially thin dielectric layer deposited over the first electrode. The on-chip by-pass capacitor also includes a second electrode formed during a deposition of a second metal layer of the multi-level deposition device, where the second electrode is formed over the substantially thin dielectric layer.

### BRIEF DESCRIPTION OF THE DRAWINGS

FIG. 1 illustrates a block diagram of an exemplary embodiment of a high-k constant MIM capacitor;

FIG. 2 illustrates a flow diagram for a fabrication process of a high-k constant MIM capacitor; and

FIGS. 3A-3E, together, illustrate a side view of an exemplary embodiment of a process to manufacture high-k constant MIM capacitor in accordance with the principles of the present invention;

### DETAILED DESCRIPTION OF A PREFERRED EMBODIMENT

For simplicity and illustrative purposes, the principles of the present invention are described by referring mainly to an exemplary embodiment of a method for manufacturing a high dielectric constant capacitor. However, one of ordinary skill in the art would readily recognize that the same principles are equally applicable to all types of capacitors, and can be implemented in any semiconductor device, and that any such variation would be within such modifications that do not depart from the true spirit and scope of the present invention. Moreover, in the following detailed description, references are made to the accompanying drawings, which illustrate specific embodiments in which the present invention may be practiced. Electrical, mechanical, logical and structural changes may be made to the embodiments without departing from the spirit and scope of the present invention. The following detailed description is, therefore, not to be taken in a limiting sense and the scope of the present invention is defined by the appended claims and their equivalents.

According to a disclosed embodiment of the present invention, a method or process of manufacturing on-chip bypass capacitors on a VLSI device (or chip) is improved by utilizing a high-dielectric constant metal-insulator-metal (MIM) capacitor manufacturing process. In one aspect, the present invention pertains to improving the relatively poor capacitance efficiency of conventional MIM capacitors by growing a thin layer of a high dielectric (high k), e.g., 10-100, constant insulator at the interface of metal lines and vias. Although the present invention contemplates using a high-k dielectric constant within a range of 4-10, it should be readily apparent that dielectric constant value may be any user-specified without departing from the scope or spirit of the present invention.

In another aspect, the present invention relates to a high-k constant MIM capacitor. The high-k constant MIM capacitor may comprise a lower electrode in a first metal layer of a VLSI device, a substantially thin layer of high-k insulator (e.g., silicon nitride, lead zirconate titanate (“PZT”), etc.,) at an interface of the first metal layer and a via, and an upper electrode form in a second metal layer. The via provides a channel between the second metal layer to the high-k insulator.

In yet another aspect of the present invention, the high-k insulator layer may be formed from a composite of materials to yield the high dielectric constant. For instant, the high-k insulator layer may be comprised of a dielectric material, e.g., PZT, in between two barrier layers. The barrier layers may be implemented with platinum or other similar conductors. The barrier layers may be used in the event that the metal of the electrodes cannot interface with the insulator. Although in a preferred embodiment of the present invention, a high-k insulator layer may be comprised of a dielectric material positioned between two barrier layers, it should be readily apparent that other combinations of materials to form a high-k dielectric constant insulator layer are contemplated by the present invention and do not depart from the scope or spirit of the invention.

In yet another aspect of the present invention, multiple vias may be placed where the upper and lower electrodes overlap forming an array of vias. The area encompassed by the array of via may form the high-k constant MIM capacitor. By controlling the number of vias in an array, the capacitance of a high-k constant MIM capacitor may be customized to a VLSI device. Moreover, since the thickness of the high-k constant insulator may be significantly smaller than a conventional MIM capacitor, the high-k constant MIM capacitor has a higher capacitance. In addition, the high-k constant of the insulator layer contributes to an increase in the capacitance per unit area of the high-k constant MIM capacitor as compared to a conventional MIM capacitor.

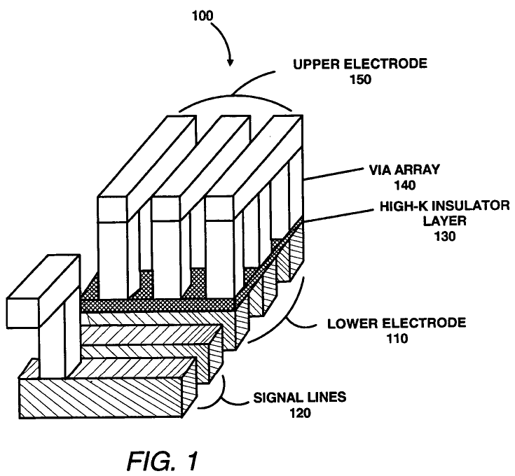

FIG. 1 illustrates an exemplary schematic of a high-k constant MIM capacitor 100. As shown in FIG. 1, a lower electrode 110 is formed during deposition of a first metal layer for signal lines 120 of a VLSI device. The lower electrode 110 may be formed among several metal signal lines in a parallel line configuration in order to avoid a dishing effect during the chemical-mechanical polishing (“CMP”) of the first metal layer. On top of the lower electrode 110, a relatively thin, e.g., 50-100 Å, high-k insulator layer 130 is deposited on top of the first metal layer of the VLSI device. Although in a preferred embodiment of the present invention, the thickness of the insulator layer 130 may range from 50-100 Å, it should be readily apparent to those skilled in the art that the thickness may be a user-designated value without departing from the scope or spirit of the present invention.

After the high-k insulator layer is deposited, a second layer of metal is deposited to form a via array 140 and an upper electrode 150. The upper electrode 150 may also be formed among several metal signal lines in a parallel line configuration to avoid the dishing effect during a subsequent CMP step. Accordingly, high-k constant MIM capacitors may be formed between any layers of metal of a multi-level VLSI device or VLSI system with a small variation in conventional fabrication techniques.

As shown in FIG. 1, the lower and upper electrodes, 110 and 150, respectively, are substantially parallel in an X-Y plane and overlap one another. It should be readily apparent to one of ordinary skill in the art that the high-k constant MIM capacitor 100 may be formed in the overlap region of the electrodes, 110 and 150, without regard to the size of the overlap.

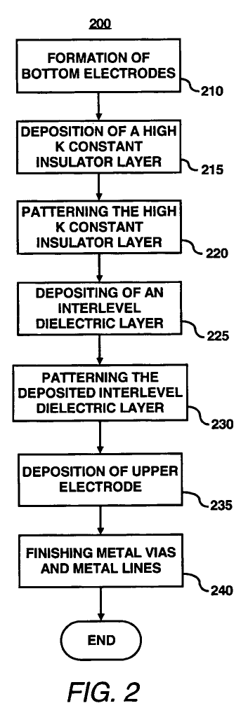

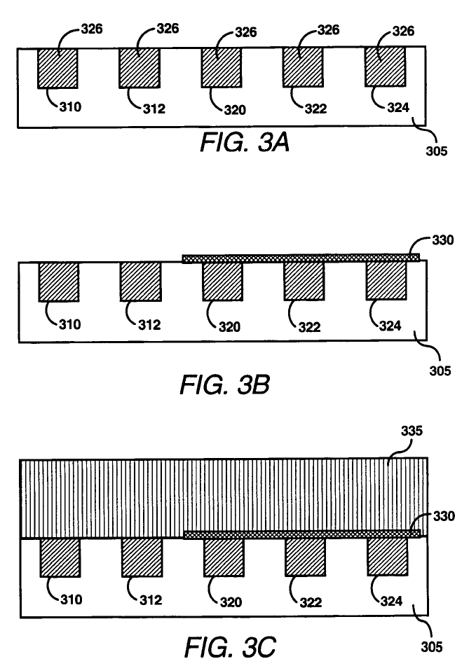

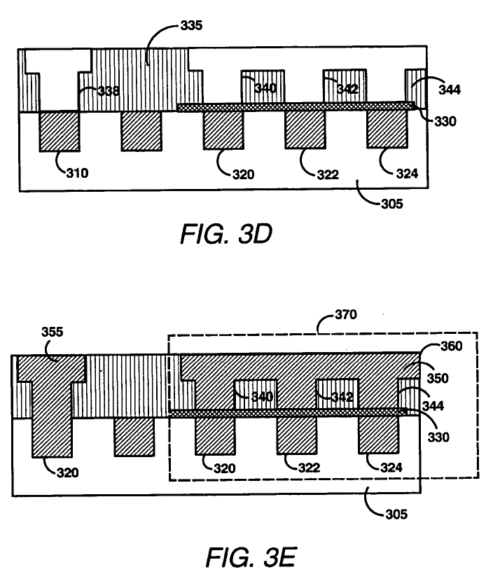

FIG. 2 illustrates an exemplary flow diagram of a fabrication process 200 for fabricating a high-k constant MIM capacitor with FIGS. 3A-3E illustrating a side view of the fabrication process 200 on an exemplary VLSI device. In particular, the fabrication process 200 may begin when spaces for signal lines 310-312 (see FIG. 3A) and bottom electrodes 320-324 are etched out of a dielectric layer 305, in step 210. After the etching, a first metal layer 326 is applied over the etched dielectric layer 305 filling in the spaces for signal lines 310-312. Subsequently, a metal mask layer (not shown) may be applied to pattern bottom electrodes 320-324 of a high-k constant MIM capacitor in the metal as well as signal lines 310-312 for the VLSI chip. The first metal layer 326 is then reduced to the bottom electrodes 320-324 and/or signal lines 310-312 by a CMP process. A CMP machine may implement the CMP process.

Returning to FIG. 2, in step 215, a high-k insulator layer, such as silicon nitride (see FIG. 3B), is deposited on top of the VLSI chip. Alternatively, a composite of materials, e.g., a composite of PZT and platinum, may be used to form the high-k insulator layer. In step 220, the high-k insulator layer is patterned and etched to form the insulator layer 330 of the high-k constant MIM capacitor over the bottom electrodes 320-324, where the thickness of the insulator layer may be between 50-100 Å. However, other user specified values for thickness are within the scope and spirit of the present invention. The patterning of the high-k insulator layer removes the high-k insulator layer from contacting the signal lines 310-312. Optionally, after the etching of the insulator layer 330, the insulator layer 330 may be polished to remove improve planarity.

Returning to FIG. 2, in step 225, an interlevel dielectric layer 335 such as silicon dioxide, silicon nitride, etc., is deposited over the VLSI chip. In particular, the interlevel dielectric 335 has been deposited over the high-k insulator layer 330 which covers the bottom electrode 320-324, the signal lines 310-312 and the dielectric 305 (see FIG. 3C).

In step 230 of FIG. 2, the interlevel dielectric layer 330 is subsequently patterned and etched to carve a space for signal via 338 (see FIG. 3D) to the signal line 310 and electrode vias 340-344 to the bottom electrodes 320-324, respectively. A second layer of signal lines may also be formed in the interlevel dielectric layer 330.

Returning to FIG. 2, in step 235, a second layer of metal 350 is deposited on top of the patterned interlevel dielectric layer 330 (see FIG. 3E) to form the signal via 355 and the electrode vias 340-344, and an upper electrode 360 of a high-k constant MIM capacitor 370. The second layer of metal is finished by a second CMP process to complete the vias 338-344 and upper electrode 360, in step 240.

Although, for illustrative purposes, the process for manufacturing only one high-k constant MIM capacitor is discussed shown in FIG. 2, it should be understood and readily apparent to those familiar with semiconductor processing that there may be any number of high-k constant MIM capacitors manufactured on a VLSI chip.

While the invention has been described with reference to the exemplary embodiments thereof, those skilled in the art will be able to make various modifications to the described embodiments of the invention without departing from the true spirit and scope of the invention. The terms and descriptions used herein are set forth by way of illustration only and are not meant as limitations. In particular, although the method of the present invention has been described by examples, the steps of the method may be performed in a different order than illustrated or simultaneously. Those skilled in the art will recognize that these and other variations are possible within the spirit and scope of the invention as defined in the following claims and their equivalents.

What is claimed is:

1. A method of forming a by-pass capacitor on a multi-level metallization device, said method comprising:
forming a first electrode in a first metal layer of said multi-level metallization device;
depositing a substantially thin dielectric material layer over said first metal layer of said multi-level metallization device; and
forming a second electrode on a second metal layer, wherein said second metal layer is formed over said substantially thin dielectric material layer.

2. The method of forming a by-pass capacitor on a multi-level metallization device according to claim 1, said method further comprising:
patterning said substantially thin dielectric material layer to substantially cover said first electrode; and
adjusting a thickness of said substantially thin dielectric material layer.

3. The method of forming a by-pass capacitor on a multi-level metallization device according to claim 2, wherein a dielectric constant of said substantially thin dielectric material layer is substantially high.

4. The method of forming a by-pass capacitor on a multi-level metallization device according to claim 3 wherein said substantially thin dielectric material layer includes silicon nitride.

5. The method of forming a by-pass capacitor on a multi-level metallization device according to claim 3, wherein said thickness of said substantially thin dielectric material layer is between 50 to 100 angstroms.

6. The method of forming a by-pass capacitor on a multi-level metallization device according to claim 3, wherein said dielectric constant of said substantially thin dielectric material layer is between 4 and 100.

7. The method of forming a by-pass capacitor on a multi-level metallization device according to claim 1, said method further comprising:
depositing an interlevel dielectric material layer over said substantially thin dielectric material layer; and
etching at least one via, said at least one via adapted to receive said second metal layer.

8. The method of forming a by-pass capacitor on a multi-level metallization device according to claim 7, said method further comprising:
patterning said second metal layer to form said second electrode; and
polishing said second metal layer.

9. The method of forming a by-pass capacitor on a multi-level metallization device according to claim 1, wherein said forming said first electrode comprises:
etching said first electrode in a dielectric layer of said multi-level metallization device.

10. The method of forming a by-pass capacitor on a multi-level metallization device according to claim 1, wherein said first electrode is formed in a parallel line configuration.

11. The method of forming a by-pass capacitor on a multi-level metallization device according to claim 1, wherein said second electrode is formed in a parallel line configuration.

12. The method of forming a by-pass capacitor on a multi-level metallization device according to claim 1, wherein said substantially thin dielectric material comprises a composite of materials.

13. The method of forming a by-pass capacitor on a multi-level metallization device according to claim 12, wherein said composite of materials includes PZT and platinum.

14. An on-chip by-pass capacitor comprising:
a first electrode formed during a deposition of a first metal layer of a multi-level deposition device;
a substantially thin dielectric layer configured to be deposited over said first electrode; and
a second electrode formed during a deposition of a second metal layer of said multi-level deposition device, wherein said second electrode is formed over said substantially thin dielectric layer.

15. The on-chip by-pass capacitor according to claim 14, wherein a dielectric constant of said substantially thin dielectric material layer is substantially high.

16. The on-chip by-pass capacitor according to claim 15, wherein said substantially thin dielectric material layer includes silicon nitride.

17. The on-chip by-pass capacitor according to claim 14, wherein said thickness of said substantially thin dielectric material layer is between 50 to 100 angstroms.

18. The on-chip by-pass capacitor according to claim 14, wherein said substantially thin dielectric material comprises a composite of materials.

19. The on-chip by-pass capacitor according to claim 18, wherein said composite of materials includes PZT and platinum.
